(19) United States
(12) Patent Application Publication
(10) Pub. No.: US 2026/0114002 A1
(43) Pub. Date: Apr. 23, 2026

(54) SILICON CARBIDE SEMICONDUCTOR DEVICE

(71) Applicant: FUJI ELECTRIC CO., LTD., Kawasaki-shi (JP)

(72) Inventors: Katsunori SUZUKI, Matsumoto-City (JP); Shingo HAYASHI, Matsumoto-City (JP); Akimasa KINOSHITA, Matsumoto-City (JP)

(73) Assignee: FUJI ELECTRIC CO., LTD., Kawasaki-shi (JP)

(21) Appl. No.: 18/924,501

(22) Filed: Oct. 23, 2024

(30) Foreign Application Priority Data
Dec. 26, 2023 (JP) 2023-219374

(51) Int. Cl. H01L 29/16; H01L 29/06; H01L 29/10; H01L 29/423; H01L 29/739; H01L 29/78

(52) U.S. Cl. CPC H10D 62/8325; H10D 30/668; H10D 62/10; H10D 62/124; H10D 62/393; H10D 64/513; H10D 12/481

(57) ABSTRACT

Provided is a SiC semiconductor device having a suppressed contact resistance. The SiC semiconductor device includes a first conductivity type drift layer containing SiC, first conductivity type main regions containing SiC, second conductivity type base regions containing SiC and in contact with the main regions, a gate electrode, and a main electrode in contact with the main regions. Each main region includes a contact region having a top face in contact with the main electrode, and the contact region contains a plurality of SiC microcrystals with 3C structure. The plurality of SiC microcrystals in the contact region include first microcrystals having a grain size not less than a threshold and second microcrystals having a grain size of less than the threshold, and in the contact region, the proportion of the first microcrystals on the top face of the contact region is 10% or more.

### CROSS-REFERENCE TO RELATED APPLICATION

This application claims benefit of priority under 35 USC 119 based on Japanese Patent Application No. 2023-219374 filed on Dec. 26, 2023, the entire contents of which are incorporated by reference herein.

### BACKGROUND OF THE INVENTION

### 1. Field of the Invention

The present disclosure relates to a SiC semiconductor device including silicon carbide (SiC).

### 2. Description of the Related Art

JP 2009-049198 A discloses a semiconductor device that is produced by implanting phosphorus ions into a substrate of hexagonal single crystal silicon carbide to form an amorphous layer, recrystallizing the amorphous layer by heat treatment into cubic single crystals of n type silicon carbide, and depositing nickel on the top surface of the n type silicon carbide to form an electrode.

WO 2017/042963 A1 discloses a semiconductor device that has, in an n⁻ type epitaxially-grown layer formed on a first main surface of an n⁺ type SiC substrate formed of 4H—SiC, an n⁺ type source region and has, in the n⁺ type source region, an n⁺ type 3C—SiC region and a p⁺ type potential fixing region. In the semiconductor device, a barrier metal film is formed in contact with the n⁺ type 3C—SiC region and the p⁺ type potential fixing region, and a source wiring electrode is formed on the barrier metal film.

JP 6795805 B1 discloses a 3C—SiC layer on a hexagonal SiC layer.

Providing nickel silicide suppresses contact resistance. To provide nickel silicide, however, many production steps including Ni film formation, etching, high temperature annealing, and unreacted substance removal by etching are required, and this has made it difficult to suppress production costs.

To address this problem, local formation of 3C—SiC (band gap: 2.23 eV) only in a contact part has been studied by ion implantation of impurities to break 4H—SiC (band gap: 3.26 eV) crystals and then annealing. This has enabled the formation of a contact structure between a source electrode and a SiC substrate only by impurity ion implantation and annealing.

Even with 3C—SiC, the contact resistance is preferably further suppressed.

### SUMMARY OF INVENTION

Under such circumstances, the present disclosure is intended to provide a SiC semiconductor device having a suppressed contact resistance.

An aspect of the disclosure is a silicon carbide semiconductor device including: a first conductivity type drift layer containing silicon carbide; a first conductivity type main region containing silicon carbide and provided on a top face side of the drift layer; a second conductivity type base region containing silicon carbide, provided on the top face side of the drift layer, and in contact with the main region; a gate electrode with a gate insulating film in contact with the base region; and a main electrode in contact with the main region. In the silicon carbide semiconductor device, the main region includes a contact region having a top face in contact with the main electrode, the contact region contains a plurality of silicon carbide microcrystals with 3C structure, the plurality of silicon carbide microcrystals in the contact region include first microcrystals having a grain size not less than a threshold and second microcrystals having a grain size less than the threshold, and in the contact region, a proportion of the first microcrystals on the top face of the contact region is 10% or more.

### BRIEF DESCRIPTION OF DRAWINGS

FIG. 1 is a plan view schematically illustrating an example of a SiC semiconductor device pertaining to a first embodiment;

FIG. 2 is a longitudinal sectional view illustrating a cross-sectional structure taken along line A-A in FIG. 1;

FIG. 3 is a view illustrating an example of the EBSD analysis result of the top face of a source contact region pertaining to the first embodiment;

FIG. 4 is a schematic view illustrating how the grain boundary between microcrystals scatters electrons;

FIG. 5 is a schematic view illustrating a longitudinal section structure when many crystal grain boundaries exist in a source contact region pertaining to a comparative example; and

FIG. 6 is a schematic view illustrating a section structure when large first microcrystals exist in a source contact region pertaining to a comparative example.

### DETAILED DESCRIPTION

A first embodiment of the present disclosure will now be described with reference to drawings. In the description of drawings, identical or similar components are indicated by an identical or similar sign and are not described. However, the drawings are schematic, and the relationship between thickness and plan dimension, the ratio of thicknesses of layers, or the like may differ from the actual ones. The dimensional relationships or ratios may differ between drawings. The first embodiment described below is merely illustrative examples of devices or methods for embodying the technical ideas of the present disclosure, and the technical ideas of the disclosure do not specify the materials, shapes, structures, arrangements, or the like of components as follows.

In the present description, the source region of a metal-oxide semiconductor field-effect transistor (MOSFET) is “one main region (first main region)” selectable as the emitter region of an insulated gate bipolar transistor (IGBT). In a thyristor such as a MOS-controlled static induction thyristor (SI thyristor), “one main region”is selectable as the cathode region. The drain region of a MOSFET is “the other main region (second main region)” of a semiconductor device that is selectable as the collector region in an IGBT and is selectable as the anode region in a thyristor. In the present description, a region simply called a “main region” means a first main region or a second main region reasonable on the basis of the general knowledge of a person skilled in the art.

In the following description, the definitions of directions such as up and down directions are merely for convenience of explanation and do not limit the technical ideas of the disclosure. For example, when an object is rotated by 90° and observed, the up and down directions are converted to left and right directions, and when an object is rotated by 180° and observed, the up and down directions are inverted, needless to say. A “top face” may also be read as a “front face”, and a “bottom face” may also be read as a “back face”.

In the following description, a case in which a first conductivity type is an n type and a second conductivity type is a p type will be described as an example. However, the relationship of the conductivity types may be inverted to set the first conductivity type to the p type and the second conductivity type to the n type. A semiconductor region denoted by n or p with + or − means that such a semiconductor region has a higher or lower impurity concentration than a semiconductor region denoted by n or p without + or −. It should be noted that a semiconductor region denoted by n and a semiconductor region denoted by the same n may not have exactly the same impurity concentration.

SiC crystals have polymorphism, and the main polymorphisms are cubic 3C and hexagonal 4H and 6H. It has been reported that at room temperature, 3C—SiC has a bandgap of 2.23 eV, 4H—SiC has a bandgap of 3.26 eV, and 6H—SiC has a bandgap of 3.02 eV. In the following description, a case in which 4H—SiC and 3C—SiC are mainly used will be illustrated.

### FIRST EMBODIMENT

### Structure of SiC Semiconductor Device

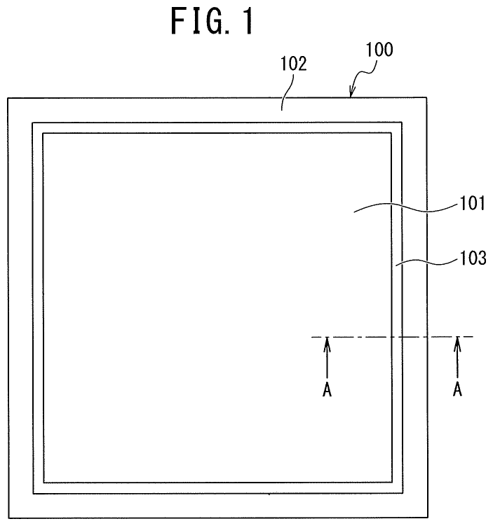

A SiC (silicon carbide) semiconductor device (semiconductor chip) 100 pertaining to a first embodiment includes, as illustrated in FIG. 1, an active part 101, for example, having a rectangular planar shape and a withstand voltage structure part 102 surrounding the periphery of the active part 101, in plan view. The SiC semiconductor device 100 also includes, between the active part 101 and the withstand voltage structure part 102, a region 103 surrounding the active part 101, in plan view.

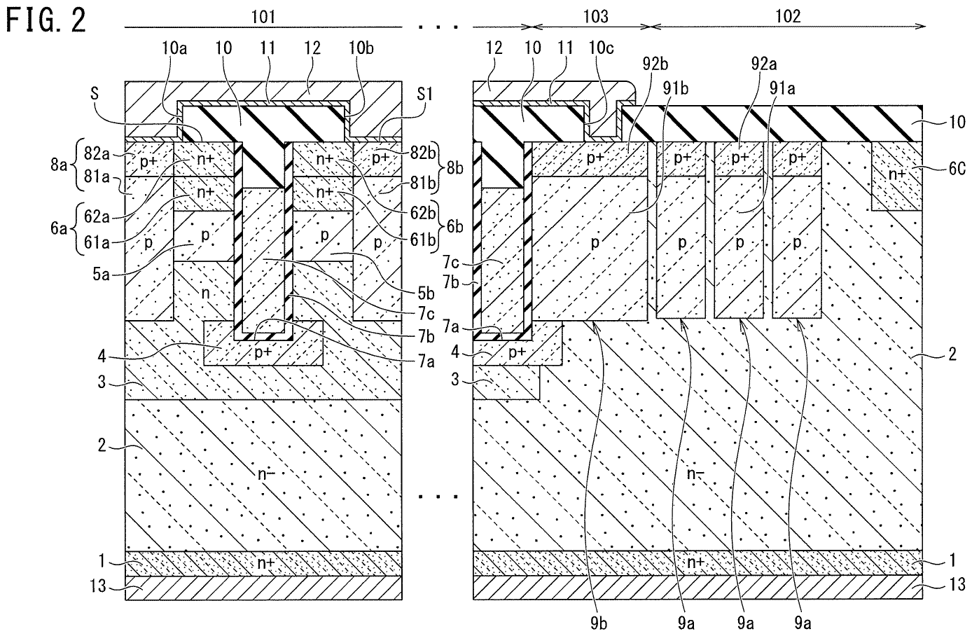

FIG. 2 is a sectional view taken along line A-A in FIG. 1. In FIG. 2, a part of the active part 101 is not illustrated. As illustrated in FIG. 2, the active part 101 includes an active element, the region 103 includes a ring region 9b, and the withstand voltage structure part 102 includes, as the termination structure, a plurality of field relaxation regions 9a described later, as an example.

As illustrated in FIG. 2, the SiC semiconductor device 100 includes a trench gate-type MOSFET as the active element, as an example. FIG. 2 illustrates one unit cell including an insulated gate electrode structure (7b, 7c) buried in a trench 7a, but in an actual device, a large number of these unit cells are arranged periodically.

The SiC semiconductor device 100 includes a first conductivity type (n⁻ type) drift layer 2 provided over the active part 101, the withstand voltage structure part 102, and the region 103. The drift layer 2 is constituted of, for example, an epitaxially-grown layer formed of SiC such as 4H—SiC. The drift layer 2 has an impurity concentration of, for example, about 1×10¹⁵ cm⁻³ or more and 5×10¹⁶ cm⁻³ or less. The drift layer 2 has a thickness of, for example, about 1 μm or more and 100 μm or less. The impurity concentration and the thickness of the drift layer 2 may be appropriately adjusted according to the withstand voltage specifications or the like.

Over the active part 101 and the region 103, a first conductivity type (n type) current spreading layer (CSL) 3 having a higher impurity concentration than the drift layer 2 is selectively provided on the top face side of the drift layer 2. The bottom face of the current spreading layer 3 is in contact with the top face of the drift layer 2. The current spreading layer 3 is formed, for example, by ion implantation of N. The current spreading layer 3 has an impurity concentration of, for example, about 5×10¹⁶ cm⁻³ or more and 5×10¹⁷ cm⁻³ or less. The current spreading layer 3 is not necessarily provided. When no current spreading layer 3 is provided, the drift layer 2 may be provided to the region of the current spreading layer 3.

In the active part 101, second conductivity type (p type) base regions 5a, 5b are selectively provided on the top face side of the current spreading layer 3. The bottom faces of the base regions 5a, 5b are in contact with the top face of the current spreading layer 3. When no current spreading layer 3 is provided, the bottom faces of the base regions 5a, 5b are in contact with the top face of the drift layer 2. The base regions 5a, 5b are, for example, regions of a SiC formed by subjecting the current spreading layer 3 to ion implantation of p type impurities such as aluminum. The base regions 5a, 5b may be constituted of an epitaxially-grown layer formed of SiC such as 4H—SiC. The base regions 5a, 5b have an impurity concentration of, for example, about 1×10¹⁶ cm⁻³ or more and 1×10¹⁸ cm⁻³ or less.

On the top face side of the current spreading layer 3, first conductivity type (n⁺ type) first main regions (source regions) 6a, 6b having a higher impurity concentration than the drift layer 2 are selectively provided. More specifically, on the top face side of the base regions 5a, 5b, source regions 6a, 6b are selectively provided. The source regions 6a, 6b are in contact with the base regions 5a, 5b. More specifically, the bottom face of the source region 6a is in contact with the top face of the base region 5a, and the bottom face of the source region 6b is in contact with the top face of the base region 5b. The source regions 6a, 6b are, for example, regions of a SiC formed by subjecting the current spreading layer 3 to ion implantation of n type impurities. The source regions 6a, 6b have an impurity concentration of, for example, about 1×10¹⁹ cm⁻³ or more and 3×10²¹ cm⁻³ or less.

The source region 6a has a multilayer structure of two layers including an n⁺ type source extension region 61a as the lower layer and an n⁺ type source contact region 62a as the upper layer. The bottom face of the source extension region 61a is in contact with the top face of the base region 5a. The top face of the source extension region 61a is in contact with the bottom face of the source contact region 62a. The source region 6b has a multilayer structure of two layers including an n⁺ type source extension region 61b as the lower layer and an n⁺ type source contact region 62b as the upper layer. The bottom face of the source extension region 61b is in contact with the top face of the base region 5b. The top face of the source extension region 61b is in contact with the bottom face of the source contact region 62b.

As described above, the source regions 6a, 6b include the source contact regions 62a, 62b at the top face side.

The source contact regions 62a, 62b are contact regions in contact with the source electrode described later.

The source contact regions 62a, 62b have an impurity concentration of, for example, about 5×10¹⁹ cm⁻³ or more and 3×10²¹ cm⁻³ or less.

The source regions 6a, 6b contain 3C—SiC and 4H—SiC. More specifically, the source extension regions 61a, 61b are formed of 4H—SiC. The source contact regions 62a, 62b contain 3C—SiC. The source contact regions 62a, 62b contain 3C—SiC at a content of, for example, about 10% or more and 100% or less. When the content of 3C—SiC is less than 100%, the source contact regions 62a, 62b may contain 4H—SiC. “Source extension regions 61a, 61b being formed of 4H—SiC” may mean “source extension regions 61a, 61b being mainly formed of 4H—SiC”. Even if the source extension regions 61a, 61b contain substances other than 4H—SiC, such as 3C—SiC, the content is very small. Hereinafter, 3C—SiC may also be called 3C structure, and 4H—SiC may also be called 4H structure.

How 3C—SiC is formed in the source contact regions 62a, 62b will next be described. First, to form 3C—SiC, 4H—SiC is subjected to ion implantation of n type impurities (first conductivity type impurities) such as phosphorus (P) and nitrogen (N) to break the 4H—SiC structure, and an amorphous structure is formed. The ion implantation temperature is set low for breaking the 4H—SiC structure. By low-temperature ion implantation of impurities at a high concentration, the 4H—SiC structure can be broken. The ion implantation temperature is set, for example, at about room temperature (for example, 20° C.) or more and 200° C. or less. The dose amount at ion implantation is set, for example, at about 5×10¹⁴ cm⁻² or more and 1×10¹⁶ cm⁻² or less. By controlling the temperature and concentration conditions for ion implantation of impurities at a low temperature and at a high concentration, the amount of microcrystals having a large grain size is increased to reduce the grain boundary. Then, heat treatment is performed to activate the ion-implanted impurities and to recrystallize the amorphous structure, and 3C—SiC is prepared. The heat treatment temperature is set, for example, at about 1,600° C. or more and 1,900° C. or less. The heat treatment temperature may be set, for example, at 1,750° C. The heat treatment is performed for about 30 minutes. The heat treatment may also serve as activation annealing for activating the impurities ion-implanted to SiC. To break the 4H—SiC structure, an inert gas element such as argon, silicon, carbon, or the like may be ion-implanted.

Forming 3C—SiC as above can suppress an increase in production costs of the SiC semiconductor device 100.

The dimension in the depth direction of the source contact regions 62a, 62b is, for example, about 50 nm or more and 100 nm or less. In consideration of the band gap from the source extension regions 61a, 61b, the dimension in the depth direction of the source contact regions 62a, 62b is preferably set at about 100 nm. The source contact regions 62a, 62b contain a plurality of first conductivity type (n⁺ type), 3C—SiC microcrystals. More specifically, the source contact regions 62a, 62b contain, as the 3C—SiC microcrystals, a plurality of first microcrystals having a grain size not less than a threshold and a plurality of second microcrystals having a grain size less than the threshold. For example, the threshold is 30 nm, the first microcrystals are microcrystals having a grain size of not less than 30 nm, and the second microcrystals are microcrystals having a grain size of less than 30 nm.

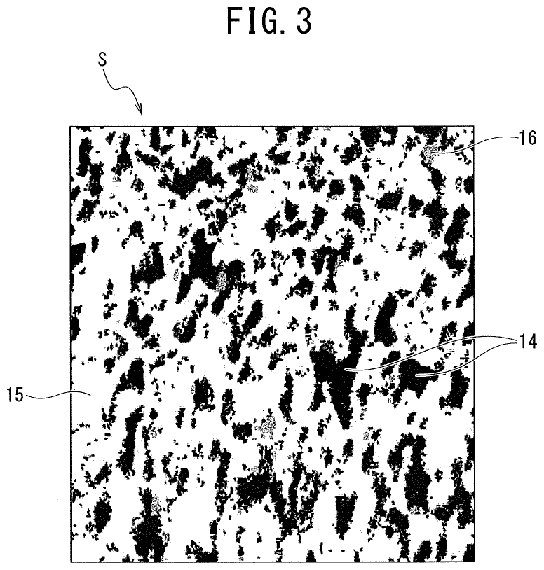

FIG. 3 is a view illustrating an EBSD (electron back scattered diffraction pattern) analysis result (phase map) of the top face (the source electrode side face) S of the source contact regions 62a, 62b. The following measurement apparatus was used for the analysis.

Thermal field emission scanning electron microscope (TFE-SEM) JSM-6500F manufactured by JEOL Ltd.

DigiView IV slow-scan CCD camera manufactured by TSL with analysis software, OIM Data Collection ver. 7.x and OIM Analysis ver. 7.x

The crystal grain size was determined from a grain size distribution chart not illustrated in the figure. The grain size distribution chart is the histogram in which the equivalent circle diameter (the diameter of a circle having an equivalent area) of each crystal grain identified in a crystal grain map is calculated, and the results are displayed. The crystal grain map is the pseudo-color map in which two or more consecutive measurement points observed within a specified azimuthal angle difference (5°) are displayed as an identical crystal grain. The average of crystal grain sizes is the average of equivalent circle diameters. More specifically, the average of crystal grain sizes (dave) of n pieces of microcrystals from a microcrystal a1 to a microcrystal an is calculated by calculating the sum of the grain sizes of n pieces grains by adding from a grain size d1 corresponding to the equivalent circle diameter of the microcrystal a1 to a grain size dn corresponding to the equivalent circle diameter of the microcrystal an, then dividing the sum by the number n of the microcrystals (dave=(d1+d2+ . . . +dn)/n).

By the EBSD method, typically, a region from the top face to a depth of about 50 nm of the object to be analyzed can be analyzed. Accordingly, a “top face” may mean not only a two-dimensional face but also a three-dimensional region from a top face to a depth of about 50 nm. Even in a region of the source contact regions 62a, 62b deeper than 50 nm, 3C—SiC microcrystals may be formed. In a region 14 in FIG. 3, a first microcrystal having a grain size of not less than 30 nm exists. The top face S has a plurality of regions 14, and one region 14 is occupied by a single first microcrystal. In other words, the boundary between the region 14 and the region 15, 16 described later is the grain boundary of a first microcrystal. In a region 15, a plurality of second microcrystals having a grain size of less than 30 nm exist. The second microcrystals are microscopic, and thus the grain boundaries thereof are not illustrated in the figure. The region 15 is occupied by a large number of second microcrystals. In a region 16, 4H—SiC microcrystals exist.

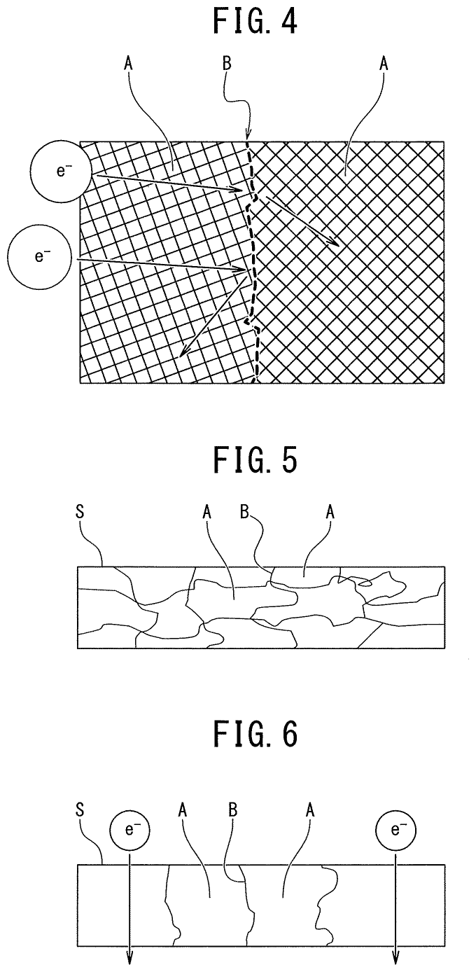

The effect of microcrystals on electrical properties will next be described. FIG. 4 illustrates two SiC microcrystals A and a grain boundary B between the microcrystals A. FIG. 5 illustrates a comparative example of a SiC semiconductor in which a large number of microcrystals having a grain size less than a threshold exist. As illustrated in FIG. 4, electrons flowing in SiC are scattered by the grain boundary B. Accordingly, if a large number of crystal grain boundaries existed as illustrated in FIG. 5, a large number of electrons could be scattered. This could impair the electron mobility to increase the electric resistance of source contact regions 62a, 62b. In contrast, a SiC semiconductor illustrated in FIG. 6 contains microcrystals having a relatively large grain size. In a semiconductor containing a large number of microcrystals having a relatively large grain size as above, the number of grain boundaries B is reduced. Hence, in the present embodiment, the number of grain boundaries between 3C—SiC microcrystals is reduced in the source contact regions 62a, 62b, and accordingly the electric resistance is reduced as bulk. This reduces the electric resistance between the source contact regions 62a, 62b and the source electrode described later.

In the present embodiment, the proportion of the first microcrystals on the top face S is 10% or more. This can reduce the number of grain boundaries to improve the electric resistance of SiC. As the proportion of the first microcrystals on the top face S is higher, the number of grain boundaries between 3C—SiC microcrystals can be reduced. Hence, the proportion of the first microcrystals on the top face S may be 15% or more or may be 20% or more. The upper limit of the proportion of the first microcrystals on the top face S is preferably as high as possible. The upper limit of the proportion of the first microcrystals on the top face S is, for example, about 50%.

The dimension along the depth direction of a microcrystal is proportional to the dimension along the horizontal direction. In other words, a first microcrystal having a larger dimension along the horizontal direction has a larger dimension along the depth direction. As first microcrystals have a larger dimension along the depth direction, the number of grain boundaries along the depth direction can be suppressed as illustrated in the comparative example in FIG. 6. As the number of grain boundaries is suppressed, electrons traveling from the top face S along the depth direction are unlikely to be scattered. The maximum grain size of the first microcrystals is, for example, about 1,000 nm.

The average grain size of the first microcrystals in the source contact regions 62a, 62b is about 60 nm or more and 400 nm or less and may be, for example, 70 nm.

The average grain size of the first microcrystals may be 60 nm or more and 80 nm or less.

As illustrated in FIG. 2, a trench 7a penetrating the source regions 6a, 6b and the base regions 5a, 5b is provided from the top faces of the source regions 6a, 6b in the normal direction of the top faces of the source regions 6a, 6b (in the depth direction). The bottom face of the trench 7a reaches the current spreading layer 3.

The trench 7a has a width of, for example, about 1 μm or less. The left face of the trench 7a is in contact with the source region 6a and the base region 5a. The right face of the trench 7a is in contact with the source region 6b and the base region 5b. The trench 7a may have a plane pattern of a stripe extending in the back direction and the front direction of the plane of FIG. 2 or may have a plane pattern of dots.

On the bottom face and both side faces of the trench 7a, a gate insulating film 7b is provided. A gate electrode 7c is buried inside the trench 7a with the gate insulating film 7b interposed. As illustrated in FIG. 2, the top face of the gate electrode 7c is located below the boundaries between the source contact regions 62a, 62b and the source extension regions 61a, 61b but is not limited to this. The top face of the gate electrode 7c may be flush with the top faces S of the source contact regions 62a, 62b. The gate insulating film 7b and the gate electrode 7c constitute a trench gate-type insulated gate electrode structure (7b, 7c).

As the gate insulating film 7b, a single layer film of one of a silicone oxide film (SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film, a composite film prepared by stacking a plurality of such films, or the like is usable. As the material of the gate electrode 7c, for example, a polysilicon layer containing p type impurities or n type impurities at a high impurity concentration (doped polysilicon layer) or a high-melting point metal such as titanium (Ti), tungsten (W), or nickel (Ni) is usable.

In the current spreading layer 3 and on the bottom part of the trench 7a, a second conductivity type (p⁺ type) gate bottom protection region 4 is provided. The top face of the gate bottom protection region 4 is in contact with the bottom face of the trench 7a. The top face of the gate bottom protection region 4 may not be in contact with the bottom face of the trench 7a. The gate bottom protection region 4 has an impurity concentration of, for example, about 1×10¹⁷ cm⁻³ or more and 1×10¹⁹ cm⁻³ or less. The gate bottom protection region 4 is, for example, a region of a SiC formed by subjecting the current spreading layer 3 to ion implantation of p type impurities. The gate bottom protection region 4 is electrically connected to a source wiring electrode 12 in a portion not illustrated in the figure. When the MOSFET is in the off-state, the region is depleted and functions to relax the electric field applied to the bottom face of the trench 7a.

On the top face side of the current spreading layer 3, second conductivity type (p type) buried regions 81a, 81b are selectively provided to be in contact with the base regions 5a, 5b. The bottom faces of the buried regions 81a, 81b are in contact with the current spreading layer 3. The side face of the buried region 81a is in contact with the current spreading layer 3 and the base region 5a, and the side face of the buried region 81b is in contact with the current spreading layer 3 and the base region 5b. The buried regions 81a, 81b are, for example, regions of a SiC formed by subjecting the current spreading layer 3 to ion implantation of p type impurities such as aluminum. The buried regions 81a, 81b have an impurity concentration of, for example, about 5×10¹⁷ cm⁻³ or more and 1×10¹⁹ cm⁻³ or less. The buried regions 81a, 81b are mainly formed of 4H—SiC and contains little 3C—SiC if any.

On the top face side of the buried regions 81a, 81b (above the current spreading layer 3), second conductivity type (p⁺ type) base contact regions 82a, 82b formed of SiC and having a higher impurity concentration than the buried regions 81a, 81b are selectively provided. The base contact regions 82a, 82b contain p⁺ type SiC. The base contact regions 82a, 82b are contact regions in contact with the source electrode described later. The bottom face of the base contact region 82a is in contact with the top face of the buried region 81a, and the side face of the base contact region 82a is in contact with the source region 6a. The base contact region 82a is electrically connected to the base region 5a. The bottom face of the base contact region 82b is in contact with the top face of the buried region 81b, and the side face of the base contact region 82b is in contact with the source region 6b. The base contact region 82b is electrically connected to the base region 5b. The base contact regions 82a, 82b are, for example, regions of a SiC formed by subjecting the current spreading layer 3 to ion implantation of p type impurities such as aluminum. The impurity concentration of the base contact regions 82a, 82b is higher than the impurity concentration of the buried regions 81a, 81b and is, for example, about 5×10¹⁹ cm⁻³ or more and 3×10²¹ cm⁻³ or less.

The base contact regions 82a, 82b may or may not contain 3C—SiC. For base contact regions 82a, 82b containing 3C—SiC, the base contact regions 82a, 82b have substantially the same structure as the structure of the source contact regions 62a, 62b other than the above. A case of base contact regions 82a, 82b containing 3C—SiC will next be described in more detail.

The dimension in the depth direction of the base contact regions 82a, 82b is, for example, about 50 nm or more and 100 nm or less. The base contact regions 82a, 82b contain a plurality of 3C—SiC microcrystals. In consideration of the band gap from the buried regions 81a, 81b, the dimension in the depth direction of the base contact regions 82a, 82b is preferably set at about 100 nm. The base contact regions 82a, 82b contain a plurality of second conductivity type (p⁺ type), 3C—SiC microcrystals. More specifically, the base contact regions 82a, 82b contain, as the 3C—SiC microcrystals, a plurality of first microcrystals having a grain size not less than a threshold and a plurality of second microcrystals having a grain size less than the threshold. For example, the threshold is 30 nm, the first microcrystals are microcrystals having a grain size of not less than 30 nm, and the second microcrystals are microcrystals having a grain size of less than 30 nm.

The EBSD analysis result of the top faces (the source electrode side face) S1 of the base contact regions 82a, 82b is substantially the same as that in FIG. 3 and thus is not illustrated in figures or not described in detail. In the present embodiment, the proportion of the first microcrystals on the top faces S1 of the base contact regions 82a, 82b is 10% or more. This can reduce the number of grain boundaries to improve the electric resistance. As the proportion of the first microcrystals on the top face S1 is higher, the number of grain boundaries between 3C—SiC microcrystals can be reduced. Hence, the proportion of the first microcrystals on the top face S1 may be 15% or more or may be 20% or more. The upper limit of the proportion of the first microcrystals on the top face S1 is preferably as high as possible. The upper limit of the proportion of the first microcrystals on the top face S1 is, for example, about 50%.

The maximum grain size of the first microcrystals in the base contact regions 82a, 82b is, for example, about 1,000 nm. The average grain size of the first microcrystals in the base contact regions 82a, 82b is about 60 nm or more and 400 nm or less and may be, for example, 70 nm. The average grain size of the first microcrystals may be 60 nm or more and 80 nm or less.

For base contact regions 82a, 82b containing no 3C—SiC, the base contact regions 82a, 82b is mainly formed of 4H—SiC and contains little 3C—SiC if any.

In the withstand voltage structure part 102, a plurality of second conductivity type (p type) field relaxation regions 9a are selectively provided on the top face side of the drift layer 2. In the example illustrated in FIG. 2, three field relaxation regions 9a are provided on the top face side of the drift layer 2. The field relaxation regions 9a are concentric guard rings (field limiting rings) in plan view but are not illustrated in figures. The field relaxation regions 9a are separated from each other by the drift layer 2. The bottom faces of the field relaxation regions 9a are in contact with the top face of the drift layer 2. Each field relaxation region 9a is, for example, a region of a SiC formed by subjecting the drift layer 2 to ion implantation of p type impurities such as aluminum. More specifically, the field relaxation region 9a is a region formed of 4H—SiC. The field relaxation region 9a includes a p type first portion 91a and a p⁺ type second portion 92a. The second portion 92a is located shallower in the depth direction than the first portion 91a, and the bottom face of the second portion 92a is in contact with the top face of the first portion 91a.

In the withstand voltage structure part 102, a first conductivity type (n⁺ type) channel stopper region 6c is provided at the outermost periphery on the top face side of the drift layer 2. The bottom face of the channel stopper region 6c is in contact with the top face of the drift layer 2. The channel stopper region 6c is, for example, a region of a 3C—SiC formed by subjecting the drift layer 2 to ion implantation of n type impurities.

In the region 103, a second conductivity type (p type) ring region 9b is selectively provided on the top face side of the drift layer 2. The bottom face of the ring region 9b is in contact with the top face of the drift layer 2. The ring region 9b is, for example, a region of a SiC formed by subjecting the drift layer 2 to ion implantation of p type impurities. More specifically, the ring region 9b is a region formed of 4H—SiC. The ring region 9b is a ring-shaped portion surrounding the edge of the active part 101 in plan view but is not illustrated in figures. The ring region 9b includes a first portion 91b and a second portion 92b. The second portion 92b is located shallower in the depth direction than the first portion 91b, and the bottom face of the second portion 92b is in contact with the top face of the first portion 91b.

On the top face side of the gate electrode 7c, the top face side of the region 103, and the top face side of the withstand voltage structure part 102, an insulating film 10 is selectively provided. In the withstand voltage structure part 102, the insulating film 10 is provided on the top faces of the field relaxation regions 9a. More specifically, the insulating film 10 is provided in positions to cover the second portions 92a of the field relaxation regions 9a. The insulating film 10, for example, includes a single layer film such as a silicone oxide film containing boron (B) and phosphorus (P) (BPSG film), a silicone oxide film containing phosphorus (P) (PSG film), a non-doped silicone oxide film called “NSG” and containing neither phosphorus (P) nor boron (B), a silicone oxide film containing boron (B) (BSG film), and a silicon nitride film (Si₃N₄ film) or a stacked-layer film thereof. The insulating film 10 has openings 10a, 10b through which the top faces of the source regions 6a, 6b and the base contact regions 82a, 82b are exposed. The insulating film 10 also has an opening 10c through which the top face of the ring region 9b, more specifically the top face of the second portion 92b, is exposed.

A first main electrode (source electrode) (11, 12) is provided so as to cover the insulating film 10, the top faces of the source regions 6a, 6b and the base contact regions 82a, 82b exposed through the openings 10a, 10b, and the top face of the ring region 9b exposed through the opening 10c. The source electrode (11, 12) includes a lower barrier metal layer 11 and an upper source wiring electrode 12. For example, the barrier metal layer 11 includes a metal such as titanium nitride (TiN), titanium (Ti), and a TiN/Ti multilayer structure in which Ti is the lower layer. The barrier metal layer 11 is in direct contact with the source regions 6a, 6b and the base contact regions 82a, 82b and is in ohmic contact with the source regions 6a, 6b and the base contact regions 82a, 82b at a low resistance. The barrier metal layer 11 is in direct contact with the second portion 92b of the ring region 9b.

The source wiring electrode 12 is electrically connected to the source regions 6a, 6b, the base contact regions 82a, 82b, and the ring region 9b with the barrier metal layer 11 interposed. The source wiring electrode 12 is provided separately from a gate wiring electrode (not illustrated) that is electrically connected to the gate electrode 7c. The source wiring electrode 12, for example, includes a metal such as aluminum (Al), aluminum-silicon (Al—Si), aluminum-copper (Al—Cu), and copper (Cu).

On the bottom face side of the drift layer 2, a first conductivity type (n⁺ type) second main region (drain region) 1 having a higher impurity concentration than the drift layer 2 is provided. The drain region 1, for example, is constituted of a semiconductor substrate (SiC substrate) formed of 4H—SiC. The drain region 1 has an impurity concentration of, for example, about 1×10¹⁸ cm⁻³ or more and 3×10²⁰ cm⁻³ or less. The drain region 1 has a thickness of, for example, about 30 μm or more and 500 μm or less. Between the drift layer 2 and the drain region 1, a dislocation conversion layer or a recombination promotion layer that is an n type buffer layer having a higher impurity concentration than the drift layer 2 and having a lower impurity concentration than the drain region 1 may be provided.

On the bottom face side of the drain region 1, a second main electrode (drain electrode) 13 is provided. As the drain electrode 13, for example, a single layer film of gold (Au) or a metal film in which titanium (Ti), nickel (Ni), and Au are stacked in this order from the drain region 1 is usable, and a metal film such as a molybdenum (Mo) film and a tungsten (W) film may be further stacked as the lowermost layer. Between the drain region 1 and the drain electrode 13, a drain contact layer such as a nickel silicide (NiSiₓ) film may be provided for ohmic contact.

The SiC semiconductor device 100 pertaining to the first embodiment during the operation applies a positive voltage to the drain electrode 13 while using the source electrode (11, 12) as a ground potential, and causes an inversion layer (a channel) to be formed in the respective base regions 5a, 5b toward the side faces of the trench 7a so as to be in the on-state when a positive voltage of a threshold or greater is applied to the gate electrode 7c. In the on-state, current flows from the drain electrode 13 through the drain region 1, the drift layer 2, the current spreading layer 3, the inversion layers of the base regions 5a, 5b, and the source regions 6a, 6b to the source electrode (11, 12). In contrast, when the voltage applied to the gate electrode 7c is less than a threshold, no inversion layers are formed in the base regions 5a, 5b, and the device is led to be the off-state. Accordingly, no current flows from the drain electrode 13 to the source electrode (11, 12).

In the SiC semiconductor device 100 pertaining to the first embodiment, at least the source contact regions 62a, 62b of the source contact regions 62a, 62b and the base contact regions 82a, 82b contain a plurality of silicon carbide microcrystals with 3C structure, the silicon carbide microcrystals include first microcrystals having a grain size not less than a threshold (30 nm) and second microcrystals having a grain size less than the threshold, and the proportion of the first microcrystals on the top faces of the source contact regions 62a, 62b or the base contact regions 82a, 82b is 10% or more. The proportion of the first microcrystals on the top face of SiC is 10% or more, and accordingly, many microcrystals having a relatively large grain size are contained. This can reduce the number of grain boundaries in pathways of electrons or holes. This can reduce the electric resistance of SiC as bulk, and can reduce the electric resistance between the source contact regions 62a, 62b and the base contact regions 82a, 82b, and the source electrode (11, 12). Accordingly, a SiC semiconductor device 100 having a low contact resistance can be produced at low costs.

### Other Embodiments

The first embodiment of the present disclosure has been described as above, but the description and drawings constituting a part of the disclosure should not be understood to limit the disclosure. From the disclosure, various alternative embodiments, examples, and operational technologies will be apparent to a person skilled in the art.

For example, as the semiconductor device pertaining to the first embodiment, a MOSFET is exemplified, but the present disclosure is also applicable to an insulated gate bipolar transistor (IGBT) having a structure in which a p⁺ type collector region is provided in place of the n⁺ type drain region 1. In addition to the IGBT alone, the present disclosure is further applicable to a reverse conduction IGBT (RC-IGBT) or a reverse blocking insulated gate bipolar transistor (RB-IGBT).

In the first embodiment, the field relaxation region 9a has been described as a guard ring, but may have a JTE structure.

The transistor of the SiC semiconductor device 100 may be a vertical transistor in which channels are formed in the depth direction or a lateral transistor in which channels are formed in the lateral direction. The transistor of the SiC semiconductor device 100 may be a planar transistor or a trench-gate transistor.

The configurations disclosed in the first embodiment may be appropriately combined or modified to the extent that no inconsistency arises. Needless to say, the disclosure includes various embodiments and the like not described in the present description. The technical scope of the present disclosure is therefore defined only by the invention specifying matters pertaining to the claims and reasonable from the above description.

1. A silicon carbide semiconductor device comprising:
a first conductivity type drift layer containing silicon carbide;
a first conductivity type main region containing silicon carbide and provided on a top face side of the drift layer;
a second conductivity type base region containing silicon carbide, provided on the top face side of the drift layer, and in contact with the main region;
a gate electrode with a gate insulating film in contact with the base region; and
a main electrode in contact with the main region, wherein
the main region includes a contact region having a top face in contact with the main electrode,
the contact region contains a plurality of silicon carbide microcrystals with 3C structure,
the plurality of silicon carbide microcrystals in the contact region include first microcrystals having a grain size not less than a threshold and second microcrystals having a grain size less than the threshold, and
in the contact region, a proportion of the first microcrystals on the top face of the contact region is 10% or more.

2. The silicon carbide semiconductor device according to claim 1, further comprising a second conductivity type base contact region containing silicon carbide, provided on the top face side of the drift layer, and electrically connected to the base region, wherein
the base contact region contains a plurality of silicon carbide microcrystals with 3C structure,
the plurality of silicon carbide microcrystals in the base contact region include first microcrystals having a grain size not less than the threshold and second microcrystals having a grain size less than the threshold, and
in the base contact region, a proportion of the first microcrystals on a top face of the base contact region is 10% or more.

3. The silicon carbide semiconductor device according to claim 1, wherein the threshold is 30 nm.

4. The silicon carbide semiconductor device according to claim 1, wherein in the contact region, the proportion of the first microcrystals on the top face of the contact region is 50% or less.

5. The silicon carbide semiconductor device according to claim 1, wherein the first microcrystals in the contact region have an average grain size of 60 nm or more and 400 nm or less.

6. The silicon carbide semiconductor device according to claim 1, wherein a dimension in a depth direction of the contact region is 50 nm or more and 100 nm or less.

7. The silicon carbide semiconductor device according to claim 1, wherein the contact region is formed by ion implantation of a first conductivity type impurity at a dose amount of 5×10¹⁴ cm⁻² or more and 1×10¹⁶ cm⁻² or less at a temperature of 20° C. or more and 200° C. or less.

8. The silicon carbide semiconductor device according to claim 1, wherein the main region is provided on a top face side of the base region, and
the gate electrode is provided inside a trench with the gate insulating film interposed, the trench penetrating the main region and the base region.

9. The silicon carbide semiconductor device according to claim 2, wherein the threshold is 30 nm.

10. The silicon carbide semiconductor device according to claim 2, wherein the main region is provided on a top face side of the base region, and
the gate electrode is provided inside a trench with the gate insulating film interposed, the trench penetrating the main region and the base region.
